(19) United States
(12) Patent Application Publication
(10) Pub. No.: US 2025/0386484 A1
(43) Pub. Date: Dec. 18, 2025

(54) SEMICONDUCTOR STRUCTURE AND FORMING METHOD THEREOF

(71) Applicant: SwaySure Technology Co., Ltd., Shenzhen (CN)

(72) Inventor: MAO-HUA SU, Shenzhen (CN)

(21) Appl. No.: 18/980,892

(22) Filed: Dec. 13, 2024

(30) Foreign Application Priority Data
Jun. 17, 2024 (CN) 20241077802.7

(51) Int. Cl. H10B 12/00; H01L 21/3213; H10D 1/00

(52) U.S. Cl. CPC H10B 12/0335; H01L 21/32139; H10D 1/043

(57) ABSTRACT

A forming method includes: forming a stacked structure on a substrate, where the stacked structure includes a first material layer and a second material layer; etching the stacked structure using a first etching gas to form a first opening penetrating through the second material layer, wherein the first etching gas includes fluoride ions; introducing a first protective gas and a first auxiliary gas simultaneously into the first opening for reaction to form a protective layer on a sidewall of the first opening; etching the stacked structure using the first etching gas to form a second opening penetrating through the first material layer; and introducing the first protective gas and the first auxiliary gas simultaneously into the second opening for a reaction to form a protective layer on a sidewall of the second opening.

### CROSS-REFERENCE TO RELATED APPLICATIONS

This application claims priority to Chinese Patent Application 202410778002.7, filed on Jun. 17, 2024, the entire disclosure of which is hereby incorporated herein by reference.

### TECHNICAL FIELD

The present disclosure relates to the field of semiconductor technology, and more specifically, to a semiconductor structure and a forming method thereof.

### BACKGROUND

With advancements in process technology, the integration degree of semiconductor devices also increases, feature sizes of the devices decrease continuously, and arrangement densities of the devices also become higher and higher. Due to size limitations, the arrangement density of components in a planar semiconductor device has been close to the limit, and therefore, in order to improve the density of the device, the semiconductor device may adopt a structure comprising a plurality of components which are vertically stacked to achieve a higher arrangement density of the device.

At present, since a multilayer component stacked structure needs to be processed in a stacking direction of films, and particularly when deep holes penetrating through the stacked structure need to be formed, defects in the etched profile of deep holes may occur. For example, the etched profile is non-collimated, which limits the structural layout and performance improvement of the semiconductor device in a stacking direction.

It should be noted that the information disclosed in the background art section above is provided solely to enhance the understanding of the background of the present disclosure, and therefore may include information that does not constitute the prior art known to those of ordinary skill in the art.

### SUMMARY OF THE INVENTION

There are provided a semiconductor structure and a forming method thereof according to embodiments of the present disclosure. The technical solution is as below:

According to an aspect of the present disclosure, there is provided a method of forming a semiconductor structure. The method comprises:
forming a stacked structure on a substrate, wherein the stacked structure comprises at least one first material layer and at least one second material layer that are stacked in a direction perpendicular to the substrate, and the first material layer and the second material layer are made of different materials;
etching the stacked structure using a first etching gas to form a first opening that penetrates through the second material layer, wherein the first etching gas comprises fluoride ions;
introducing a first protective gas and a first auxiliary gas simultaneously into the first opening for reaction to form a protective layer on a sidewall of the first opening, wherein the first protective gas comprises silicon ions, and the first auxiliary gas comprises oxygen ions;
etching the stacked structure using the first etching gas to form a second opening that penetrates through the first material layer, wherein orthographic projections of the second opening and the first opening on the substrate at least partially overlap; and
introducing the first protective gas and the first auxiliary gas simultaneously into the second opening for reaction to form a protective layer on a sidewall of the second opening.

### BRIEF DESCRIPTION OF THE DRAWINGS

The accompanying drawings, which are incorporated in and constitute a part of this specification, illustrate embodiments in accordance with the present disclosure, and are used together with the description to explain the principles of the present disclosure. Obviously, the accompanying drawings in the following description are merely some embodiments of the present disclosure. For those of ordinary skill in the art, other drawings can also be derived from these drawings without creative efforts.

FIG. 1 is a flow diagram of a method of forming a semiconductor structure in an exemplary embodiment of the present disclosure.

FIG. 2 is a structural schematic diagram of an existing semiconductor structure in an exemplary embodiment of the present disclosure.

FIG. 3 is a structural schematic diagram of the semiconductor structure with a formed stacked structure in an exemplary embodiment of the present disclosure.

FIG. 4 is a structural schematic diagram of the semiconductor structure with a stacked structure formed in an exemplary embodiment of the present disclosure.

FIG. 5 is a schematic diagram of the semiconductor structure with a patterned mask structure formed in an exemplary embodiment of the present disclosure

FIG. 6 is a structural schematic diagram of the semiconductor structure with a first opening formed in an exemplary embodiment of the present disclosure.

FIG. 7 is a structural schematic diagram of the semiconductor structure with a first opening formed in an exemplary embodiment of the present disclosure.

FIG. 8 is a structural schematic diagram of the semiconductor structure with a second opening, having a protective layer, formed in an exemplary embodiment of the present disclosure.

FIG. 9 is a structural schematic diagram of the semiconductor structure with an opening, having a protective layer, formed in an exemplary embodiment of the present disclosure.

FIG. 10 is a structural schematic diagram of a target semiconductor structure in an exemplary embodiment of the present disclosure.

FIG. 11 is a final structural schematic diagram of the semiconductor structure in an exemplary embodiment of the present disclosure.

FIG. 12 is a structural schematic diagram of a semiconductor structure with a stacked structure formed in another exemplary embodiment of the present disclosure.

FIG. 13 is a structural schematic diagram of the semiconductor structure with a mask structure formed in another exemplary embodiment of the present disclosure.

FIG. 14 is a schematic diagram of the semiconductor structure with a patterned mask structure formed in another exemplary embodiment of the present disclosure

FIG. 15 is a structural schematic diagram of the semiconductor structure with a first opening formed in another exemplary embodiment of the present disclosure.

FIG. 16 is a structural schematic diagram of the semiconductor structure with a first opening, having a protective layer, formed in another exemplary embodiment of the present disclosure.

FIG. 17 is a structural schematic diagram of the semiconductor structure with a second opening, having a protective layer, formed in another exemplary embodiment of the present disclosure.

FIG. 18 is a structural schematic diagram of the semiconductor structure with a third opening, having a protective layer, formed in another exemplary embodiment of the present disclosure.

FIG. 19 is a structural schematic diagram of the semiconductor structure with an opening, having a protective layer, formed in another exemplary embodiment of the present disclosure.

FIG. 20 is a structural schematic diagram of a target semiconductor structure in another exemplary embodiment of the present disclosure.

FIG. 21 is a final structural schematic diagram of the semiconductor structure in another exemplary embodiment of the present disclosure.

### DETAILED DESCRIPTION OF EMBODIMENTS

Example embodiments will now be described in greater detail with reference to the accompanying drawings. Example embodiments may, however, be embodied in many alternate forms and should not be construed as limited to the embodiments set forth herein. Instead, these example embodiments are provided so that this disclosure will be thorough and complete, and will fully convey the concept of the example embodiments to those skilled in the art. Identical reference numerals in the drawings denote identical or similar structures, and thus detailed descriptions of these structures will be omitted. In addition, the drawings are only schematic illustrations of the present disclosure, and are not necessarily drawn to scale.

Although relative terms such as “upper”, “lower”, etc., are used to describe the relative relationship of one component of an icon to another component, these terms are used in this specification for convenience only, for example, based on the orientation of the example shown in the drawings. It will be understood that if the device is turned or flipped upside down, the component described as being “upper” will become the “lower” component. When a structure is “on” the other structure, it may refer to the structure being integrally formed on the other structure, or the structure being “directly” disposed on the other structure, or the structure being “indirectly” disposed on the other structure through another structure.

The terms “a”, “an”, “the”, “said”, and “at least one” are used to indicate one or more elements/components/etc.; the terms “comprising” and “having” are used to denote an open-ended inclusion, mean that there may be additional elements/components/etc. In addition to those listed elements/components/etc.; the terms “first”, “second”, “third”, etc., are used merely as labels, and are not intended to limit the number of objects to which they refer.

In the related art, in order to improve the memory density and performance of a memory and achieve a smaller size, memory designs can utilize vertically stacked memory cells to increase the effective storage capacity of the memory, thereby providing more storage space within the same physical space. This offers new possibilities for high performance, high density, and low power consumption in electronic devices.

However, a capacitor, as an indispensable component in the memory, can also achieve structural design requirements of higher capacitance density, better performance and smaller size through stacked designs. The design of the capacitor may take advantage of the spatial distribution of electrodes and dielectric layers to increase the effective surface area of the capacitor, thereby providing a higher capacitance value within the same physical space. For example, a stacked capacitor is realized by stacking a plurality of electrodes and dielectric layers in a vertical direction, so as to increase the capacitance value thereof.

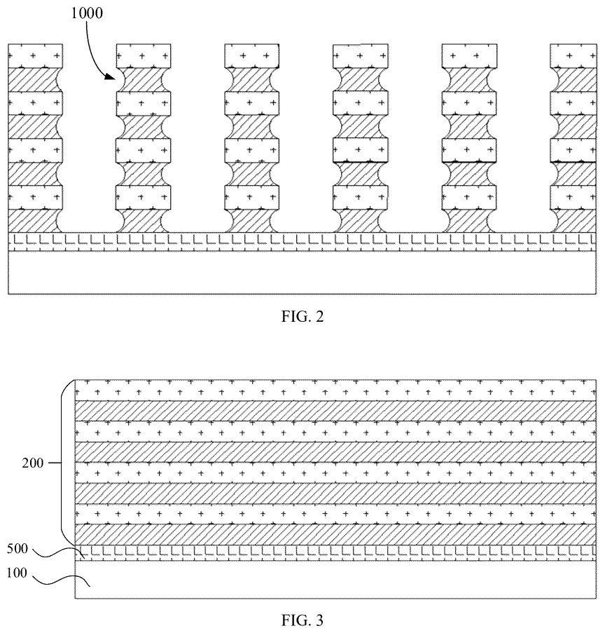

However, as the number of stacked layers increases, defects may be formed during the deep hole etching process. For instance, when etching different material layers, as shown in FIG. 2, varying etching characteristics may result in notches 1000 in sidewalls of etched deep holes, which can adversely affect the overall performance of subsequent devices and the structural layout of the devices.

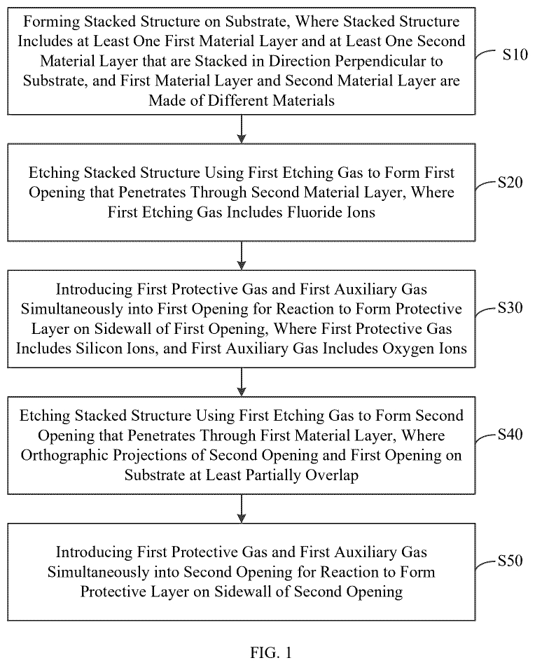

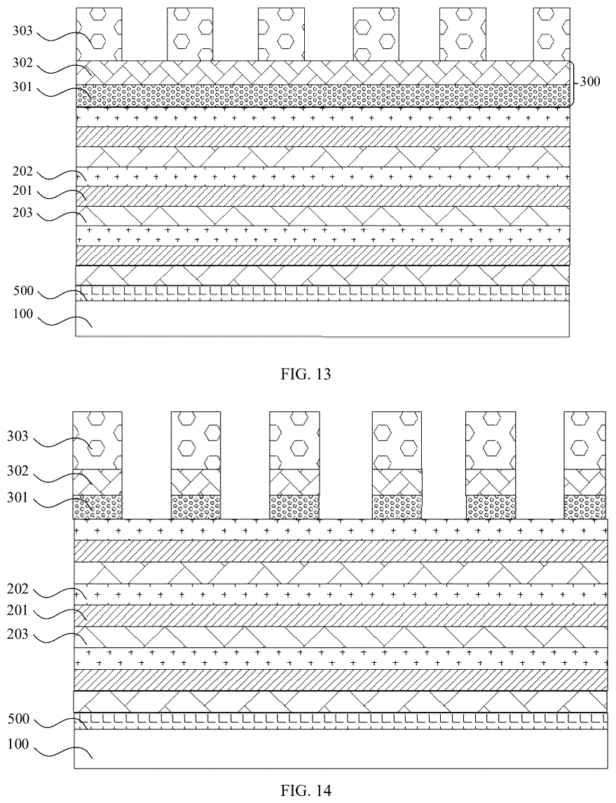

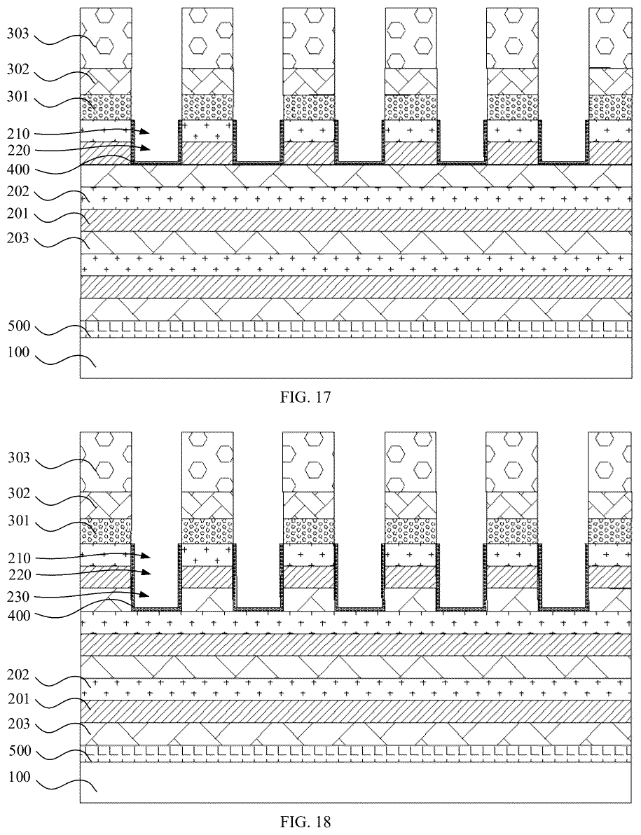

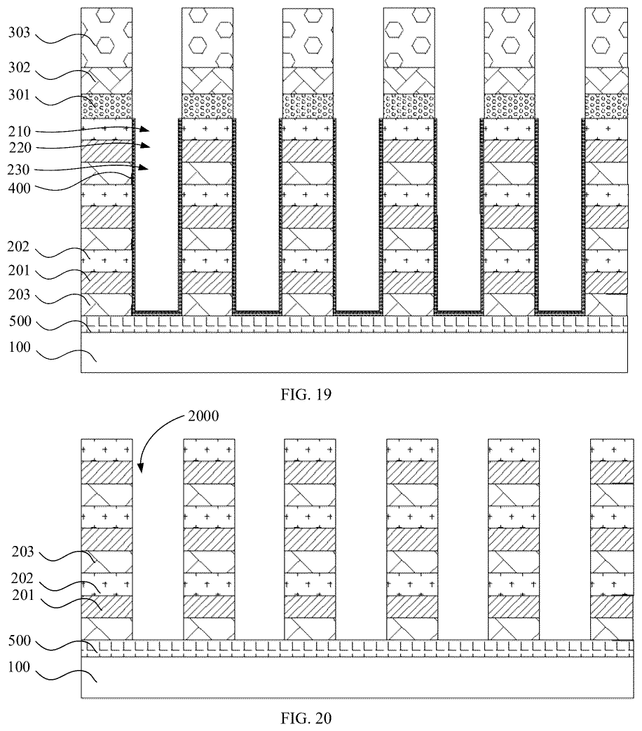

Based on this, embodiments of the present disclosure provide a method of forming a semiconductor structure. As shown in FIG. 1, in conjunction with FIGS. 3 to 21, the forming method includes: steps S10 to S50.
Step S10: forming a stacked structure 200 on a substrate 100, wherein the stacked structure 200 includes at least one first material layer 201 and at least one second material layer 202 that are stacked in a direction perpendicular to the substrate 100, and the first material layer 201 and the second material layer 202 are made of different materials;
Step S20: etching the stacked structure 200 using a first etching gas to form a first opening 210 that penetrates through the second material layer 202, where the first etching gas includes fluoride ions;
Step S30: introducing a first protective gas and a first auxiliary gas simultaneously into the first opening 210 for reaction to form a protective layer 400 on a sidewall of the first opening 210, where the first protective gas includes silicon ions, and the first auxiliary gas includes oxygen ions;
Step S40: etching the stacked structure 200 using the first etching gas to form a second opening 220 that penetrates through the first material layer 201, where orthographic projections of the second opening 220 and the first opening 210 on the substrate 100 at least partially overlap; and
Step S50: introducing the first protective gas and the first auxiliary gas simultaneously into the second opening 220 for reaction to form a protective layer 400 on a sidewall of the second opening 220.

According to the method of forming the semiconductor structure provided in the present disclosure, the first protective gas and the first auxiliary gas are introduced while an opening 2000 is etched in the stacked structure 200, the first protective gas and the first auxiliary gas can form the protective layer 400 on a sidewall of the opening 2000, thereby protecting the structure of an etched portion of the opening 2000 from damage caused by etching gas during subsequent etching. In turn, the sidewall of the opening 2000 formed in the stacked structure 200 is perpendicular to the substrate 100, breaking the limitation of the number of stacked film layers in the stacked structure 200. This increases the density of the device, optimizes the structural layout of the device, and enhances the performance of the device.

The steps of the method of forming the semiconductor structure provided in the embodiments of the present disclosure will be described below in detail with reference to the accompanying drawings.

In the embodiment provided in the present disclosure, Step S10 involves, as shown in FIG. 3, forming a stacked structure 200 on a substrate 100, wherein the stacked structure 200 comprises at least one first material layer 201 and at least one second material layer 202 that are stacked in a direction perpendicular to the substrate 100, and the first material layer 201 and the second material layer 202 are made of different materials.

The substrate 100 may be a semiconductor substrate, for example, may be a silicon (is) substrate, a germanium (Ge) substrate, a silicon germanium (Ge Si) substrate, a silicon-on-insulator (SOI) or a germanium-on-insulator (GOI). In some embodiments, the semiconductor substrate may also be a substrate comprising other elemental semiconductors or compound semiconductors, for example, silicon carbide (SiC), indium phosphide (InP), or gallium arsenide (GaAs), etc. The embodiments provided in the present disclosure are described by taking the substrate 100 being a substrate including silicon (Si) ions as an example. Naturally, for other types of substrates, corresponding modifications or improvements can be made to the embodiments of the present disclosure, all of which fall within the protection scope of the present disclosure.

The stacked structure 200 is formed on the substrate 100. The stacked structure 200 comprises at least one first material layer 201 and at least one second material layer 202, where the number of the first material layer 201 and the second material layer 202 in the stacked structure 200 can be selected according to the actual design requirements of a device structure. For example, the number of the first material layer 201 and the second material layer 202 may be one, two, four, six, eight, or even more. The greater the number of material layers in the stacked structure 200, the higher the arrangement density of the formed device structure. The first material layer 201 and the second material layer 202 are made of different materials.

In the present disclosure, the first material layer 201 may be a conductive layer, a dielectric layer 600, or a semiconductor layer; the material of the first material layer may include metals such as tungsten (W) and copper (Cu), or semiconductor layers such as polysilicon (poly); or dielectric layers 600 such as silicon nitride (SiNₓ), and the like. The second material layer 202 may be an isolation layer or an insulating layer, such as silicon oxide (SiOₓ), and the like. In the following embodiments, the first material layer 201 being tungsten and the second material layer 202 being silicon oxide are used as examples for illustration. However, if other materials are used for the first material layer 201 and the second material layer 202, adaptive modifications can be made to the following embodiments of the present disclosure herein, which all fall within the scope of protection of the present disclosure.

The first material layer 201 may be formed by Chemical Vapor Deposition (CVD), such as Atmospheric Pressure Chemical Vapor Deposition (APCVD), Low Pressure Chemical Vapor Deposition (LPCVD), or Atomic Layer Deposition (ALD); or Physical Vapor Deposition (PVD), such as sputtering or electron beam evaporation (E-beam Evaporation); or Atomic Layer Epitaxy (ALE); or Chemical Vapor Infiltration (CVI), among other methods. The second material layer 202 may be formed by one or more of the described methods, which will not be repeated here.

In the embodiments provided in the present disclosure, as shown in FIG. 3, before step S10, the forming method further includes: forming an etch stop layer 500 on the substrate 100, where the stacked structure 200 is formed on the side of the etch stop layer 500 away from the substrate 100. The etch stop layer 500 covers the surface of the substrate 100. When etching the stacked structure 200, since the etch stop layer 500 has a lower etch selectivity ratio relative to the substrate 100 and film layers in the stacked structure 200, the etch stop layer 500 can protect the film layers located thereunder from damage, thereby ensuring structural integrity and precision of the process.

The etch stop layer 500 may be made of a material such as aluminum oxide (AlOₓ), titanium nitride (TiN), etc., and the thickness thereof may be 20 nm (nano) to 100 nm (nano), for example, 20 nm, 30 nm, 40 nm, 50 nm, 60 nm, 70 nm, 80 nm, 90 nm, 100 nm, etc., and the thickness thereof may be adaptively selected according to the thickness of the film layers located thereon and an etching method to ensure the protection effect of the etch stop layer 500 on the film layers thereunder.

After the opening 2000 penetrating through the stacked structure 200 is formed, the opening 2000 may extend into or penetrate through the etch stop layer 500 to ensure the vertical size of the opening 2000. Of course, the bottom of the opening 2000 may also be flush with the surface of the etch stop layer 500, and the opening 2000 only needs to expose the surface of the etch stop layer 500.

The substrate 100 below the etch stop layer 500 may further comprise a circuit layer (not shown in the figure), the circuit layer can comprise a driving circuit or a wiring structure, and the opening 2000 can penetrate through the etch stop layer 500, so that the opening 2000 is in communication with the circuit layer, and a device located on the etch stop layer 500 can be electrically connected to the circuit layer through the opening 2000. Of course, other structures may also be formed on the semiconductor structure to establish an electrical connection with the circuit layer, for example, structures such as a conductive lead. In this case, the opening 2000 does not need to penetrate through the etch stop layer 500, which is not specifically described herein.

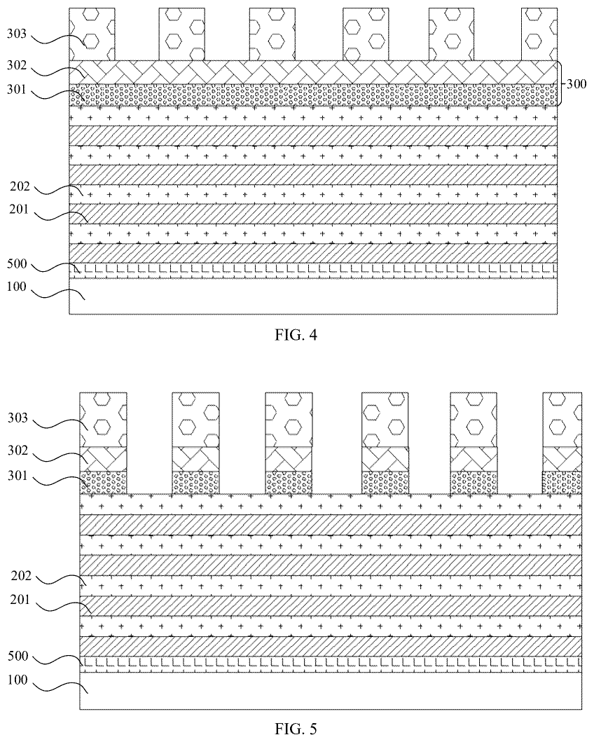

In the embodiments provided in the present disclosure, after step S10, the forming method further includes: as shown in FIG. 4, forming a mask structure 300 on the side of the stacked structure 200 away from the substrate 100, where the mask structure 300 comprises a first mask layer 301 and a second mask layer 302, and the first mask layer 301 and the second mask layer 302 are made of different materials.

The first mask layer 301 is formed on the side of the stacked structure 200 away from the substrate 100. The first mask layer 301 may be a Bottom Anti-Reflective Coating (BARC), an Anti-Reflective Coating for Photoresist (APF), a Top Anti-Reflective Coating (TARC), an Organic Anti-Reflective Coating (OARC), an Inorganic Anti-Reflective Coating (IARC) or Self-Anti-Reflective Photoresist and the like, which are used to reduce or eliminate reflection during the photolithography process, thereby improving pattern transfer accuracy and resolution. The first mask layer 301 may be positive or negative, and may be selected according to the type of the subsequent photoresist and the requirements of the photolithography process.

The second mask layer 302 may be made of a material such as aluminum oxide (AlO_{X}) or titanium nitride (TiN). After forming the second mask layer 302, as shown in FIG. 5, the forming method further includes: forming a photoresist layer 303 on the side of the second mask layer 302 away from the substrate 100; patterning the photoresist layer 303; and etching the second mask layer 302 using the patterned photoresist layer 303 to form a patterned second mask layer 302. A corresponding etching agent may be selected for the patterned second mask layer 302 according to the material thereof. In some embodiments, when the second mask layer 302 is aluminum oxide, dry etching may be selected, and the etching agent may be chlorine gas and boron trichloride. In some embodiments, wet etching may also be used for the patterning of the second mask layer 302.

In the present disclosure, after the mask structure 300 is formed, during the subsequent etching of the stacked structure 200, the patterned mask structure 300 may be used as a mask, and etching is carried out in a preset direction in the stacked structure 200.

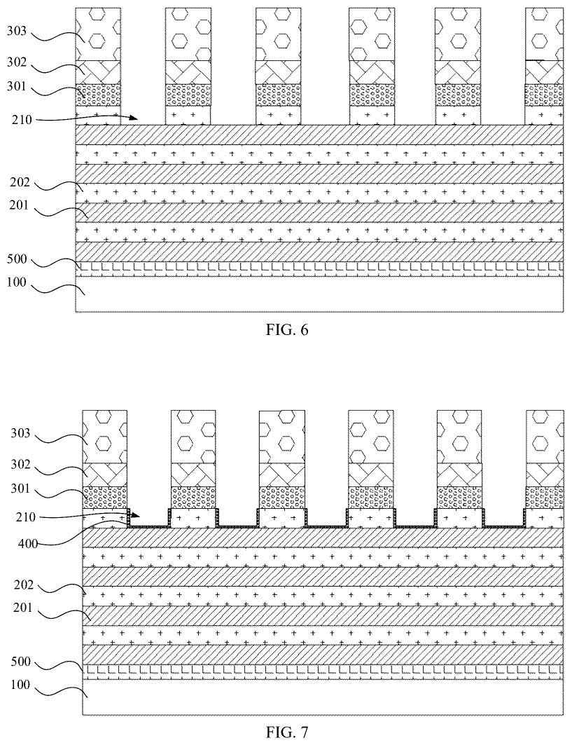

In the embodiments provided in the present disclosure, as shown in FIG. 6, Step S20 involves etching the stacked structure 200 using a first etching gas to form a first opening 210 that penetrates through the second material layer 202, wherein the first etching gas comprises fluoride ions.

The first etching gas may be C_{X}F_{Y}, S_{X}F_{Y}, and N_{X}F_{Y}, where X is a positive integer greater than or equal to 1, and Y is a positive integer greater than or equal to 1. Specifically, the first etching gas may be one or more of etching gases containing fluoride ions, such as CF₄, C₄F₆, C₄F₈, SF₆ or NF₃.

Taking the first etching gas being C_{X}F_{Y} as an example, the second material layer 202 at the top of the stacked structure 200 is etched using the patterned mask structure 300 and the first etching gas, where the first etching gas decomposes into carbon ions and fluoride ions in a reaction chamber, and the fluoride ions bombard the second material layer 202 to etch the second material layer 202, wherein SiO₂+F⁻→SiF₄↑O₂↑, SiF₄ and O₂ can be removed in a gas form, enabling the etching of a silicon dioxide film layer and the formation of the first opening 210 within the second material layer 202. In some embodiments, oxygen in mixed gas of SiF₄ and O₂ can be purified and reused, thereby promoting recycling of resources and benefiting the environment.

In the embodiments provided in the present disclosure, as shown in FIG. 7, Step S30 involves introducing a first protective gas and a first auxiliary gas simultaneously into the first opening 210 for reaction to form a protective layer 400 on a sidewall of the first opening 210, wherein the first protective gas comprises silicon ions, and the first auxiliary gas comprises oxygen ions.

The first auxiliary gas may be at least one of silicon tetrachloride (SiCl₄), monosilane (SiH₄), silylene (SiH₂), disilane (Si₂H₆) or silicate, wherein the silicate is a salt-containing silicon ions, and the composition thereof can be determined according to practical usage requirements. The first auxiliary gas may be at least one of oxygen (O₂), methanol (CH₃OH) or ethanol (C₂H₅OH).

Using the first protective gas being silicon tetrachloride (SiCl₄) and the first auxiliary gas being oxygen (O₂) as an example, the first protective gas and the first auxiliary gas react to generate the protective layer 400, and the protective layer 400 is attached to the sidewall of the first opening 210, wherein the reaction process is SiCl₄+O₂→SiO₂+Cl₂↑, silicon dioxide forms the protective layer 400, and the chlorine gas is pumped away; during the subsequent etching process, the protective layer 400 can ensure that the shape of the sidewall of the first opening 210 is not damaged, thereby ensuring the integrity of the first opening 210. Of course, chlorine gas can also be separated and recycled.

Similarly, if other gases are used for the first protective gas and first auxiliary gas, the reaction process thereof includes a chemical reaction of Si⁺+O⁻→SiO₂, and a generated by-product can be removed or vaporized, so that silicon dioxide is deposited on the sidewall of the first opening 210 to form the protective layer 400.

It should be noted that, when the protective layer 400 is formed on the sidewall of the first opening 210, due to limitations of the process, the protective layer 400 is formed at the bottom of the first opening 210 (the surface of the first material layer 201) at the same time, as shown in FIGS. 7 to 9 and FIGS. 16 to 19. However, during subsequent etching of the first material layer 201, the protective layer 400 at the bottom of the first opening 210 is removed. In addition, protective layers 400 (not shown in the drawings) will also be formed on a sidewall and a top surface of the mask structure 300. However, this does not affect the protective effect of the protective layer 400 on the sidewall of the opening 2000. During the subsequent process steps of removing the protective layer 400, the protective layers 400 formed on the surface and the sidewall of the mask structure 300 can be removed at the same time.

In some embodiments, there may be two introduction nodes for introducing the first auxiliary gas and the first protective gas into the first opening 210. First method: after the first opening 210 is formed, the two mixed gases are introduced into the first opening 210, allowing the two gases to react to generate the protective layer 400 to cover the sidewall of the first opening 210, and this method can simplify the process. Second method: during the formation of the first opening 210, the two mixed gases are introduced into part of the formed first opening 210, that is, the mixed gas mixed by the first auxiliary gas and a first protective gas are introduced during the process of etching the second material layer 202 to form the protective layer 400 in the etching process, and this method can improve the collimation of the sidewall of the opening. Of course, for different second material layers 202, the same introduction node may be used, and different introduction nodes may also be used, which may be selected as required according to an actual process.

In the embodiments provided in the present disclosure, the reaction conditions for the first auxiliary gas and the first protective gas are as follows:

A gas flow rate of the first protective gas ranges from 10 sccm (cubic centimeter flow per minute) to 100 sccm, for example, may be 10 sccm, 20 sccm, 30 sccm, 40 sccm, 50 sccm, 60 sccm, 70 sccm, 80 sccm, 90 sccm, or 100 sccm. A gas flow rate of the first auxiliary gas ranges from 100 sccm to 500 sccm, for example, may be 100 sccm, 200 sccm, 300 sccm, 400 sccm, or 500 sccm. The flow rates of the first protective gas and the first auxiliary gas can be adaptively adjusted within the described ranges according to actual process requirements.

The reaction pressure ranges from 5 mT (millitorr per square meter) to 30 mT, for example, may be 5 mT, 10 mT, 15 mT, 20 mT, 25 mT, or 30 mT. The reaction pressure can be selected and adjusted according to actual process requirements.

The reaction bias voltage ranges from 1000 W to 1500 W, for example, may be 1000 W, 1100 W, 1200 W, 1300 W, 1400 W, or 1500 W. The reaction bias voltage can be selected and adjusted according to actual process requirements.

In the embodiments provided in the present disclosure, as shown in FIG. 8, Step S40 involves further etching the stacked structure 200 using the first etching gas to form the second opening 220 that penetrates through the first material layer 201, wherein orthographic projections of the second opening 220 and the first opening 210 on the substrate 100 at least partially overlap.

The first material layer 201 is further etched using the first etching gas, where the first etching gas decomposes into carbon ions and fluoride ions in a reaction chamber, and the fluorine ions bombard the first material layer 201 to etch the first material layer 201, wherein W+F⁻→WF₆↑, WF₆ is removed in a gas form, enabling the etching of tungsten and the formation of the second opening 220 within the first material layer 201.

Since the first material layer 201 and the second material layer 202 are made of different materials, etch selectivity ratios thereof differ under the same etching gas and etching conditions, resulting in the formation of the first opening 210 and the second opening 220 being not entirely identical or similar. In particular, the second material layer 202 exhibits a tendency towards the anisotropic etching in etching characteristics, so that the sidewall of the formed first opening 210 is relatively collimated. The first material layer 201 exhibits a tendency towards the isotropic etching in etching characteristics, and the profile of the sidewall of the formed second opening 220 is in a curved shape, i.e., orthographic projections of the first opening 210 and the second opening 220 on the substrate 100 partially overlap.

To improve the overall structure and shape of the opening 2000, a protective layer 400 may be formed on the sidewall of the second opening 220 during the etching of the first material layer 201, so as to prevent the first etching gas from further etching the sidewall of the second opening 220 during the etching of the first material layer 201, thereby avoiding the occurrence of a curved sidewall of the second opening 220.

In the embodiments provided in the present disclosure, as shown in FIG. 8, Step S50 involves introducing a first protective gas and a first auxiliary gas into the second opening 220 for reaction to form a protective layer 400 on a sidewall of the second opening 220.

After forming the second opening 220 in the first material layer 201, the first protective gas and the first auxiliary gas are introduced into the second opening 220, reacting the first protective gas with the first auxiliary gas, where the reaction process is SiCl₄+O₂→SiO₂+Cl₂↑, wherein the protective layer 400 is formed by silicon dioxide, chlorine gas is pumped away, and during the subsequent etching process, the protective layer 400 can ensure that the shape of the sidewall of the second opening 220 is not damaged, thereby ensuring the integrity of the second opening 220.

Additionally, the first protective gas and the first auxiliary gas used herein are the same as or similar to the first protective gas and the first auxiliary gas introduced into the first opening 210, and specific types and reaction conditions thereof are not described again.

In some embodiments, there may be two introduction nodes for introducing the first auxiliary gas and the first protective gas into the second opening 220. First method: after the second opening 220 is formed, the two mixed gases are introduced into the second opening 220, allowing the two gases to react to generate the protective layer 400 to cover the sidewall of the second opening 220, and this method can simplify the process. Second method: during the formation of the second opening 220, the two mixed gases are introduced into part of the formed second opening 220, that is, the mixed gas mixed by the first auxiliary gas and a first protective gas are introduced during the process of etching the first material layer 201 to form the protective layer 400 in the etching process, and this method can ensure higher collimation of the sidewall of the opening. Of course, for different first material layers 201, the same introduction node may be used, and different introduction nodes may also be used, which may be selected as required according to an actual process.

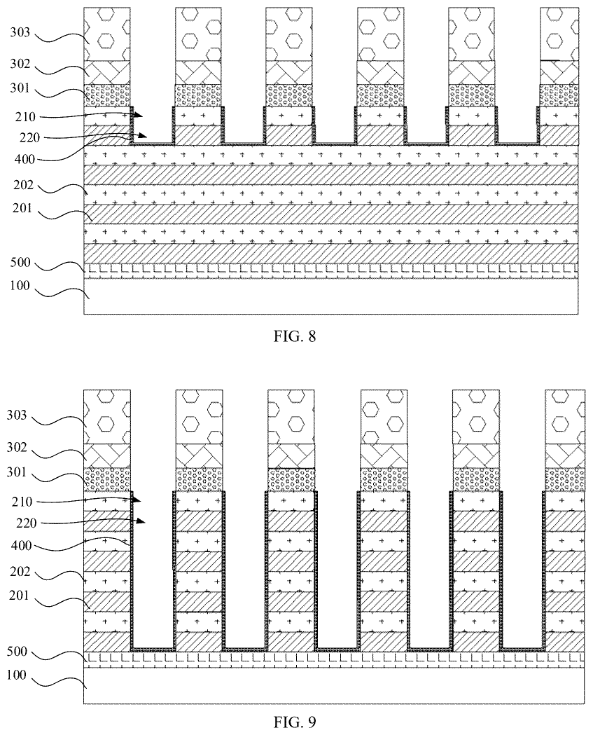

Similarly, as shown in FIG. 9, the process of forming the protective layer 400 provided in the above-mentioned embodiments can be alternately implemented in multiple film layer pairs. During the etching of each film layer, the protective layer 400 is formed in a film layer in which the opening 2000 has been formed to protect the shape of the sidewall of the opening 2000 from being damaged by the subsequent etching process, thereby ensuring the integrity of the opening 2000. Especially when a high-aspect ratio contact (HARC) hole is formed in the semiconductor structure, the forming method provided in the present disclosure can ensure the structural integrity and collimation of the HARC, and provide a good structural foundation for the subsequent formation of the device.

The aspect ratio of the described HARC structure can be understood as this, when the aspect ratio is greater than or equal to 5:1, the requirement on the aspect ratio of the HARC structure can be achieved, and of course, different aspect ratios can also be selected according to actual design requirements of the device.

Furthermore, as shown in FIGS. 12 to 21, to increase the adhesion between the first material layer 201 and the second material layer 202, a third material layer 203 can be formed between the first material layer 201 and the second material layer 202, wherein the first material layer 201, the second material layer 202, and the third material layer 203 are made of different materials.

The third material layer 203 may be made of a material such as titanium nitride (TiN), and may be formed by chemical vapor deposition (CVD), such as plasma-enhanced chemical vapor deposition (PECVD); or physical vapor deposition (PVD), such as sputtering, E-beam evaporation and ion plating; or atomic layer deposition (ALD); or electrochemical deposition; or laser cladding.

It should be noted that, the third material layer 203 is formed between at least one pair of the first material layer 201 and the second material layer 202, for example, the third material layer may be formed between each pair of adjacent film layers in the stacked structure 200, or may be located between some adjacent film layers, and the formation position of the third material layer 203 may be adaptively arranged according to an actual structure.

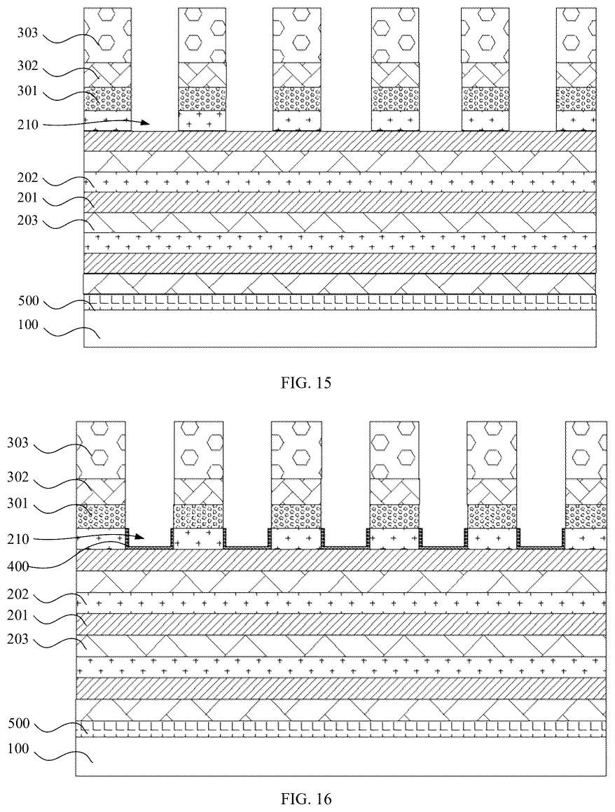

As shown in FIGS. 15 to 18, when the stacked structure 200 comprises the third material layer 203, the method further includes:

etching the third material layer 203 using a second etching gas to form a third opening 230 penetrating through the third material layer 203, wherein orthographic projections of the first opening 210, the second opening 220 and the third opening 230 on the substrate 100 at least partially overlap; the second etching gas comprises chloride ions; and the first auxiliary gas and the first protective gas are introduced into the third opening 230 and initiate a reaction to form a protective layer 400 on a sidewall of the third opening 230.

The second etching gas may be chlorine gas. During the formation of the third opening 230, the third material layer 203 can be etched using the chlorine gas. The reaction process may include W+Cl⁻→WCl₄↑, tungsten tetrachloride is removed to form the third opening 230 penetrating through the third material layer 203.

After forming the third opening 230, the first protective gas and the first auxiliary gas are introduced into the third opening 230, reacting the first protective gas with the first auxiliary gas, where the reaction process is SiCl₄+O₂→SiO₂+Cl₂↑, wherein the protective layer 400 is formed by silicon dioxide, chlorine gas can be recycled, and during the subsequent etching process, the protective layer 400 can ensure that the shape of the sidewall of the third opening 230 is not damaged, thereby ensuring the integrity of the third opening 230.

In some embodiments, there may be two introduction nodes for introducing the first auxiliary gas and the first protective gas into the third opening 230. First method: after the third opening 230 is formed, the two mixed gases are introduced into the third opening 230, allowing the two gases to react to generate the protective layer 400 to cover the sidewall of the third opening 230, and this method can simplify the process. Second method: during the formation of the third opening 230, the two mixed gases can be introduced into part of the formed third opening 230, that is, the mixed gas mixed by the first auxiliary gas and a first protective gas are introduced during the process of etching the third material layer 203 to form the protective layer 400 in the etching process, and this method can ensure higher collimation of the sidewall of the formed opening. Of course, for different third material layers 203, the same introduction node may be used, and different introduction nodes may also be used, which may be selected as required according to an actual process.

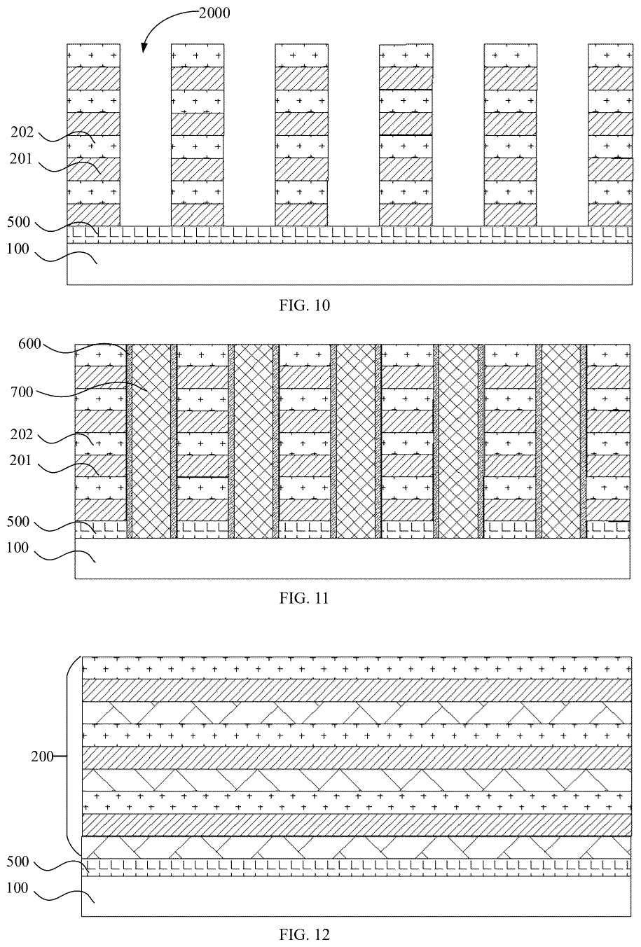

In the embodiments provided in the present disclosure, as shown in FIGS. 10 and 20, after forming the opening 2000 penetrating through the stacked structure 200, the forming method further includes: removing the protective layer 400, and forming the opening 2000 with a collimated sidewall within the stacked structure 200 that penetrates through the stacked structure 200 to form a target semiconductor structure.

It should be noted that, in the present disclosure, collimation of the sidewall of the opening 2000 may refer to that the sidewall of the opening 2000 is perpendicular to the surface of the substrate 100, and the term “perpendicular” here may refer to the strictly perpendicular, that is, the sidewall of the opening 2000 is strictly at 90 degrees with respect to the substrate 100; or it may also be referred to as being approximately perpendicular. Due to limitations to the process, the sidewall of the opening 2000 may be approximately perpendicular to the substrate 100, for example, an angle between the sidewall of the opening and the substrate may be between 85 degrees and 105 degrees, and in such cases, the sidewall of the opening 2000 may be regarded as being collimated.

The protective layer 400 can be removed by methods such as wet chemical etching, dry chemical etching, etc. For example, when wet chemical etching is used, silicon dioxide can be etched using hydrofluoric acid (HF) or a mixed solution thereof (such as buffered hydrofluoric acid (BHF)).

In the embodiments of the present disclosure, as shown in FIGS. 10 and 20, the forming method further includes: removing the mask structure 300 to expose the surface of the stacked structure 200. Removing the mask structure 300 includes removing the first mask layer 301 and the second mask layer 302. For example, the methods such as chemical mechanical polishing (CMP), wet chemical etching, and dry chemical etching may be used, and a corresponding removal method may be used according to a material specifically selected for the mask structure 300.

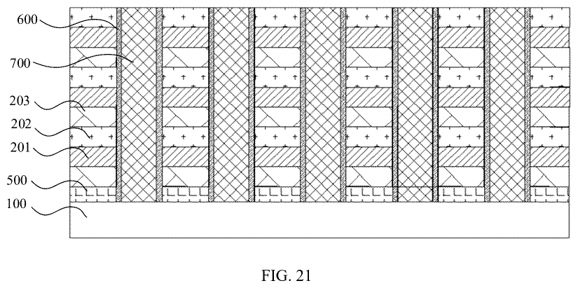

In the embodiments provided in the present disclosure, as shown in FIGS. 11 and 21, the forming method may also include: conformally forming the dielectric layer 600 in the opening 2000 of the target semiconductor structure; and forming a conductive material layer 700 in the opening 2000 so that the surface of the conductive material layer 700 is flush with the surface of the stacked structure 200.

The dielectric layer 600 may be a high-dielectric constant film layer such as hafnium oxide (HfO₂), zirconium oxide (ZrO₂), hafnium aluminate oxide (HfAlO), zirconium hafnium oxide (ZrHfO), strontium titanate oxide (SrTiO₃), strontium niobium oxide (SrNbO₃), strontium tantalum oxide (SrTaO₃), or barium titanium oxide (BaTiO₃). The conductive material layer 700 may be made of materials such as aluminum (Al), copper (Cu), gold (Au), tungsten (W), or titanium (Ti), etc.

According to the method of forming the semiconductor structure provided in the present disclosure, the first protective gas and the first auxiliary gas are introduced while the opening 2000 is etched in the stacked structure 200, the first protective gas and the first auxiliary gas can form the protective layer 400 on the sidewall of the opening 2000, thereby protecting the structure of an etched portion of the opening 2000 from damage caused by etching gas during subsequent etching. In turn, the sidewall of the opening 2000 formed in the stacked structure 200 is perpendicular to the substrate 100, breaking the limitation of the number of stacked film layers in the stacked structure 200. This increases the density of the device, optimizes the structural layout of the device, and enhances the performance of the device.

It should be noted that, although the steps of the method of forming the semiconductor structure in the present disclosure are described in a specific order in the drawings, it is not required or implied that the steps must be executed in the specific order, or all the steps shown must be executed to achieve a desired result. Additionally or alternatively, some steps may be omitted, the multiple steps may be combined into one step for execution, and/or one step is divided into multiple steps for execution, etc.

The embodiments of the present disclosure further provide a semiconductor structure. As shown in FIG. 10, the semiconductor structure comprises a substrate 100, a stacked structure 200 and an opening 2000.

The stacked structure 200 is formed on the substrate 100. The stacked structure 200 comprises at least one first material layer 201 and at least one second material layer 202 that are stacked in a direction perpendicular to the substrate 100, and the first material layer 201 and the second material layer 202 are made of different materials; the opening 2000 penetrates through the stacked structure 200; the opening 2000 comprises a first opening 210 and a second opening 220, wherein the first opening 210 penetrates through the second material layer 202, and the second opening 220 penetrates through the first material layer 201; and orthographic projections of the first opening 210 and the second opening 220 with a protective layer 400 on the substrate 100 overlap, and a sidewall of the opening 2000 is perpendicular to the surface of the substrate 100.

The semiconductor structure provided in the present disclosure has an opening 2000 with a collimated sidewall that penetrates through the stacked structure 200, having good device structural integrity and functionality.

In the embodiments provided in the present disclosure, as shown in FIG. 21, the stacked structure 200 further comprises a third material layer 203, wherein the third material layer 203 is formed between the first material layer 201 and the second material layer 202; the opening 2000 further comprises a third opening 230, the third opening 230 penetrates through the third material layer 203, and a protective layer 400 is formed on a sidewall of the third opening 230; and orthographic projections of the first opening 210 with the protective layer 400 and the third opening 230 with the protective layer 400 on the substrate 100 overlap, thereby ensuring the integrity and collimation of the opening 2000 formed within the stacked structure 200.

The semiconductor structure provided in the present disclosure can be formed by the method of forming the semiconductor structure described above, and the specific structure of the semiconductor structure can refer to the embodiments provided in the forming method.

The semiconductor structure provided in the present disclosure may be applied to a memory such as a dynamic random access memory (DRAM), a static random access memory (SRAM), and a flash memory. Of course, it can also be applied to other memory devices not listed here, which will not be enumerated herein.

Those skilled in the art will readily conceive of other embodiments of the present disclosure after considering the specification and practicing the invention disclosed herein. This application is intended to cover any variations, uses, or adaptations of the disclosure that follow the general principles of the present disclosure and include common knowledge or conventional technical means in the technical field that are not disclosed in the disclosure. The specification and embodiments are only regarded as examples, and the real scope and spirit of this disclosure are defined by the appended claims.

What is claimed is:

1. A method of forming a semiconductor structure, comprising:
forming a stacked structure on a substrate, wherein the stacked structure comprises at least one first material layer and at least one second material layer that are stacked in a direction perpendicular to the substrate, and the at least one first material layer and the at least one second material layer are made of different materials;
etching the stacked structure using a first etching gas to form a first opening that penetrates through the at least one second material layer, wherein the first etching gas comprises fluoride ions;
introducing a first protective gas and a first auxiliary gas simultaneously into the first opening for reaction to form a protective layer on a sidewall of the first opening, wherein the first protective gas comprises silicon ions, and the first auxiliary gas comprises oxygen ions;
etching the stacked structure using the first etching gas to form a second opening that penetrates through the at least one first material layer, wherein orthographic projections of the second opening and the first opening on the substrate at least partially overlap; and
introducing the first protective gas and the first auxiliary gas simultaneously into the second opening for reaction to form a protective layer on a sidewall of the second opening.

2. The method of forming the semiconductor structure according to claim 1, wherein the stacked structure further comprises a third material layer, the third material layer is located at least between one pair of the at least one first material layer and the at least one second material layer, and the at least one first material layer, the at least one second material layer and the third material layer are made of different materials; and the method further comprises:
etching the third material layer using a second etching gas to form a third opening penetrating through the third material layer, wherein orthographic projections of the first opening, the second opening and the third opening on the substrate at least partially overlap, wherein the second etching gas comprises chloride ions; and
introducing the first auxiliary gas and the first protective gas into the third opening for reaction to form a protective layer on a sidewall of the third opening.

3. The method of forming the semiconductor structure according to claim 2, comprising:
after forming the first opening, introducing the first protective gas and the first auxiliary gas simultaneously into the first opening; or
during formation of the first opening, introducing the first protective gas and the first auxiliary gas simultaneously and continuously into the formed first opening.

4. The method of forming the semiconductor structure according to claim 2, comprising:
after forming the second opening, introducing the first protective gas and the first auxiliary gas simultaneously into the second opening; or
during formation of the second opening, introducing the first protective gas and the first auxiliary gas simultaneously and continuously into the formed second opening.

5. The method of forming the semiconductor structure according to claim 2, comprising:
after forming the third opening, introducing the first protective gas and the first auxiliary gas simultaneously into the third opening; or
during formation of the third opening, introducing the first protective gas and the first auxiliary gas simultaneously and continuously into the formed third opening.

6. The method of forming the semiconductor structure according to claim 2, further comprising:
removing each protective layer to form an opening in the stacked structure, thereby forming a target semiconductor structure, wherein the opening has a collimated sidewall and penetrates through the stacked structure.

7. The method of forming the semiconductor structure according to claim 2, wherein after forming the stacked structure on the substrate, the method further comprises:
forming a mask structure on a side of the stacked structure away from the substrate, wherein the mask structure comprises a first mask layer and a second mask layer, and the first mask layer and the second mask layer are made of different materials; and
etching the stacked structure using the mask structure, the first etching gas and the second etching gas.

8. The method of forming the semiconductor structure according to claim 7, comprising:
forming a photoresist layer on a side of the second mask layer away from the substrate;
patterning the photoresist layer; and
etching the second mask layer using the patterned photoresist layer to form a patterned second mask layer.

9. The method of forming the semiconductor structure according to claim 1, wherein before forming the stacked structure, the method further comprises:
forming an etch stop layer on the substrate, wherein the stacked structure is formed on a side of the etch stop layer away from the substrate; and
after forming an opening penetrating through the stacked structure, the opening extending into the etch stop layer or penetrating through the etch stop layer.

10. The method of forming the semiconductor structure according to claim 1, wherein a gas flow rate of the first protective gas is 10 sccm to 100 sccm, and a gas flow rate of the first auxiliary gas is 100 sccm to 500 sccm.

11. The method of forming the semiconductor structure according to claim 1, comprising:
reacting the first auxiliary gas with the first protective gas under a pressure of 5 mT to 30 mT.

12. The method of forming the semiconductor structure according to claim 1, comprising:
reacting the first auxiliary gas with the first protective gas under a bias voltage of 1000 W to 1500 W.

13. The method of forming the semiconductor structure according to claim 1, wherein the first protective gas comprises at least one of silicon tetrachloride, monosilane, silylene, disilane, or silicate.

14. The method of forming the semiconductor structure according to claim 1, wherein the first auxiliary gas comprises at least one of oxygen, methanol or ethanol.

15. The method of forming the semiconductor structure according to claim 1, wherein the first etching gas comprises C_{X}F_{Y}, S_{X}F_{Y}, and N_{X}F_{Y}, wherein X is a positive integer greater than or equal to 1, and Y is a positive integer greater than or equal to 1.

16. The method of forming the semiconductor structure according to claim 2, wherein the second etching gas comprises chlorine gas.
